(19) United States
(12) Patent Application Publication
(10) Pub. No.: US 2013/0319500 A1
(43) Pub. Date: Dec. 5, 2013

(54) ELECTRICITY-GENERATING FABRIC PANEL UNIT

(71) Applicants: Daniel Lee BIZZELL, Charlotte, NC (US); Faramarz FARAHI, Charlotte, NC (US); Jeremy Eric LOSAW, Charlotte, NC (US); Raeshon Lamont MCNEIL, Charlotte, NC (US); Kenneth C. PAULUS, Charlotte, NC (US); Thomas James PHILPOTT, Charlotte, NC (US); Juan Carlos PEREZ, Charlotte, NC (US)

(72) Inventors: Daniel Lee BIZZELL, Charlotte, NC (US); Faramarz FARAHI, Charlotte, NC (US); Jeremy Eric LOSAW, Charlotte, NC (US); Raeshon Lamont MCNEIL, Charlotte, NC (US); Kenneth C. PAULUS, Charlotte, NC (US); Thomas James PHILPOTT, Charlotte, NC (US); Juan Carlos PEREZ, Charlotte, NC (US)

(21) Appl. No.: 13/843,133

(22) Filed: Mar. 15, 2013

Related U.S. Application Data
(60) Provisional application No. 61/654,865, filed on Jun. 2, 2012.

(51) Int. Cl. H01L 31/052

(52) U.S. Cl. CPC H01L 31/0525
USPC 136/245

(57) ABSTRACT

An electricity-generating fabric panel unit includes a panel of light-collecting fabric and an edge assembly disposed along an edge of the fabric panel and adapted to collect light from the fabric panel and convert it to electricity.

### CROSS-REFERENCE TO RELATED APPLICATION

The present application is a U.S. nonprovisional patent application of, and claims priority under 35 U.S.C. §119(e) to, U.S. provisional patent application Ser. No. 61/654,865, filed Jun. 2, 2012, which provisional patent application is hereby incorporated herein by reference in its entirety.

### COPYRIGHT STATEMENT

All of the material in this patent document is subject to copyright protection under the copyright laws of the United States and other countries. The copyright owner has no objection to the facsimile reproduction by anyone of the patent document or the patent disclosure, as it appears in official governmental records but, otherwise, all other copyright rights whatsoever are reserved.

### BACKGROUND OF THE PRESENT INVENTION

1. Field of the Present Invention

The present invention relates generally to fabric panel units for generating electricity, and, in particular, to panel units using fabrics produced from optical waveguides that collect light and guide it to photovoltaic interfaces for conversion to electricity.

2. Background

New forms of energy-generation devices, techniques and technologies continue to be sought as companies, researchers and governments continue to try to address the world's energy problems.

New optical waveguides have been or are being developed that can receive and capture light and guide it to the ends thereof, where it can be directed against photovoltaic cells. Such waveguides are described in Farahi U.S. nonprovisional patent application Ser. No. 12/853,867, filed Aug. 10, 2010, which nonprovisional patent application published Sep. 29, 2011 as U.S. patent application publication no. 2011/0232211, which patent application and publication are incorporated by reference herein.

However, there remains a need for fabric structures and fabric panel units that may take advantage of such technology.

### SUMMARY OF THE PRESENT INVENTION

Broadly defined, the present invention according to one aspect is an electricity-generating fabric panel unit, including: a panel of light-collecting fabric produced at least partly from optical waveguides and having an edge and an edge assembly disposed along the edge of the fabric panel and adapted to collect light from the optical waveguides of the fabric panel and convert the light to electricity.

In a feature of this aspect, the optical waveguide are flexible optical waveguides. In a further feature, the panel of light-collecting fabric is woven from optical waveguides. In still further features, the panel of light-collecting fabric is woven from fiber optical waveguides; the panel of light-collecting fabric is woven from fiber optical waveguides that extend in both the longitudinal and lateral directions; the panel of light-collecting fabric is woven from fiber optical waveguides that extend in either the longitudinal direction or the lateral direction, but not both; the panel of light-collecting fabric is woven from fiber optical waveguides interspersed with wool fibers; the panel of light-collecting fabric is woven from fiber optical waveguides interspersed with cotton fibers; the panel of light-collecting fabric is woven from fiber optical waveguides interspersed with polyester fibers; and/or the panel of light-collecting fabric is woven from fiber optical waveguides interspersed with nylon fibers. In still further features, the panel of light-collecting fabric is produced from a combination of fiber optical waveguides and a conformal composite material; the panel of light-collecting fabric is produced from a combination of fiber optical waveguides and fiberglass; the panel of light-collecting fabric is produced from a combination of fiber optical waveguides and carbon fiber; and/or the panel of light-collecting fabric is produced from a combination of fiber optical waveguides and an aramid synthetic fiber.

In a further feature, the edge assembly includes a photovoltaic interface. In still further features, the photovoltaic interface includes a strip of photovoltaic cells disposed to receive light directly from exit ports of the optical waveguides.

In a further feature, the edge of the fabric panel is a first edge and the edge assembly is a first edge assembly, wherein the fabric panel further includes a second edge, and wherein the fabric panel unit further includes a second edge assembly disposed along the second edge of the fabric panel and adapted to collect light from the optical waveguides of the fabric panel and convert the light to electricity. In still further features, the first and second edges of the fabric panel are opposite each other.

Broadly defined, the present invention according to another aspect is an electricity-generating fabric panel unit, including: a panel of light-collecting fabric having an edge; and an edge assembly, adapted to collect light from the fabric panel and convert the light to electricity, that is disposed along the edge of the fabric panel and includes a housing into which the edge of the fabric panel extends.

In a feature of this aspect, the housing includes two case sections attached on opposite surfaces of the fabric panel.

In a further feature, the two case sections are clamped on opposite surfaces of the fabric panel; a gasketing material is disposed between each surface of the fabric panel and a respective one of the two case sections; the gasketing material is foam that is epoxy-bonded to the fabric panel; the two case sections are hinged together; the two case sections are held together at least partly by hook snaps; the two case sections are held together at least partly by posts extending from a strip attached to the fabric panel; the two case sections are held together at least partly by fasteners.

In a further feature, a photovoltaic interface is disposed within the housing; the photovoltaic interface includes a strip of photovoltaic cells disposed to receive light directly from exit ports of the optical waveguides; the housing defines an interior cavity, and wherein the strip of photovoltaic cells is supported by a wall structure disposed within the interior cavity at a distance from the lateral walls of the cavity; and/or the photovoltaic interface includes two strips of photovoltaic cells, each strip being angled relative to the path of light received from the exit ports of the optical waveguides, and also being angled relative to each other. In still further features, an electrical connector is electrically connected to an output of the photovoltaic interface; the electrical connector is at least partly disposed within the housing.

In a further feature, the housing is a first housing, and wherein the electrical connector is at least partly disposed in an electrical housing attached to the first housing; the electrical connector includes a male connector; the electrical connector includes a female connector; and/or a dummy plug is connected to the connector.

Broadly defined, the present invention according to another aspect is an electricity-generating fabric panel unit, including: a panel of light-collecting fabric having an edge; and an edge assembly, adapted to collect light from the fabric panel and convert the light to electricity, that is disposed along the edge of the fabric panel and includes a hinge structure for hingedly coupling the panel unit to another object having a complementary hinge structure.

In a feature, the hinge structure includes a portion of a barrel hinge; the hinge structure includes two loops of the barrel hinge; the hinge structure includes three loops of the barrel hinge.

In a further feature, the hinge structure includes a portion of a clevis hinge; hinge structure includes a clevis portion of a clevis hinge; the hinge structure includes a tang portion of a clevis hinge; the hinge structure is a first hinge structure.

In a further feature, the edge assembly includes a second separate, spaced-apart hinge structure for hingedly coupling the panel unit to an object having a complementary hinge structure; the first hinge structure is adapted for hingedly coupling the panel unit to a first object, and wherein the second hinge structure is adapted for hingedly coupling the panel unit to a second object; the first and second hinge structures are each adapted for hingedly coupling the panel unit to the same object; the first and second hinge structures are each located along a side of the edge assembly; and/or the first hinge structure is disposed at a first end of the edge assembly and extends in a first direction, wherein the second hinge structure is disposed at a second, opposite end of the edge assembly and extends in a second direction, and wherein the first and second directions are substantially opposite each other.

Broadly defined, the present invention according to another aspect is an electricity-generating fabric panel unit, including: a panel of light-collecting fabric having a first edge and a second edge; a first edge assembly disposed along the first edge of the fabric panel and adapted to collect light from the fabric panel and convert the light to electricity; and a second edge assembly disposed along the second edge of the fabric panel and adapted to collect light from the fabric panel and convert it to electricity.

In a feature, the first and second edges of the fabric panel are opposite each other; the fabric panel is stretched between the first and second edge assemblies; the first and second edge assemblies are connected by a rigid bridge to maintain the first and second edge assemblies at a fixed distance apart; the brides are bridge ties; the brides are bridge struts; the fabric panel is woven from fibers that extend in both the longitudinal and lateral directions, and the edge assemblies are disposed at the ends of the fibers that extend in the longitudinal direction; and/or the fabric panel is woven from fibers that extend in both the longitudinal and lateral directions, wherein the edge assemblies are disposed at the ends of the fibers that extend in the lateral direction.

Broadly defined, the present invention according to another aspect is a multi-unit electricity-generating fabric panel unit including: a first electricity-generating fabric panel unit, including: a first panel of light-collecting fabric having an edge, and a first edge assembly disposed along the edge of the fabric panel and adapted to collect light from the first fabric panel and convert the light to electricity; and a second electricity-generating fabric panel unit, including: a second panel of light-collecting fabric having an edge, and a second edge assembly disposed along the edge of the second fabric panel and adapted to collect light from the first fabric panel and convert the light to electricity; where the first and second electricity-generating fabric panel units are coupled together.

In a feature, a multi-unit electricity-generating fabric panel unit where the first and second electricity-generating fabric panel units are structurally attached together; the first and second electricity-generating fabric panel units are hingedly coupled to one another; the first and second electricity-generating fabric panel units are electrically connected together; and/or the first and second electricity-generating fabric panel units are electrically connected together via connectors and jumper cables.

In a further feature, an multi-unit electricity-generating fabric panel unit where each of the first and second panels of light-collecting fabric is produced at least partly from flexible optical waveguides; where each of the first and second panels of light-collecting fabric is woven from the flexible fiber optical waveguides and/or nonwoven fabric made from optical waveguide films; where each of the first and second panels of light-collecting fabric is produced from a combination of fiber optical waveguides and a conformal composite material; where each of the first and second edge assemblies includes a photovoltaic interface; where the edge of the first fabric panel is a first edge; the first fabric panel further includes a second edge; and the first fabric panel unit further includes a third edge assembly disposed along the second edge of the first fabric panel and adapted to collect light from the optical waveguides of the first fabric panel and convert the light to electricity.

In a further feature, an multi-unit electricity-generating fabric panel unit where each of the first and second edge assemblies includes a housing into which the edge of one of the respective first and second fabric panels extends; each housing includes two case sections attached on opposite surfaces of the respective fabric panel; and a photovoltaic interface is disposed within each housing; and an electrical connector is electrically connected to an output of the photovoltaic interface.

In a further feature, an multi-unit electricity-generating fabric panel unit where each of the first and second edge assemblies includes a hinge structure for hingedly coupling the respective panel unit to another object having a complementary hinge structure; each hinge structure includes a portion of a barrel hinge; each hinge structure includes a portion of a clevis hinge; and the hinge structure of each respective edge assembly is a first hinge structure of such edge assembly, and where the respective edge assembly includes a second separate, spaced-apart hinge structure for hingedly coupling the respective panel unit to an object having a complementary hinge structure.

In a further feature, an multi-unit electricity-generating fabric panel unit where the edge of the first fabric panel is a first edge of the first fabric panel; the edge of the second fabric panel is a first edge of the second panel; the first electricity-generating fabric panel unit further includes a third edge assembly disposed along a second edge of the first fabric panel, the second edge of the first fabric panel being opposite the first edge of the first fabric panel; the second electricity-generating fabric panel unit further includes a fourth edge assembly disposed along a second edge of the second fabric panel, the second edge of the second fabric panel being opposite the first edge of the second fabric panel; the first fabric panel is stretched between the first and third edge assemblies, and wherein the second fabric panel is stretched between the second and fourth edge assemblies; the first and second edge assemblies are connected by a rigid bridge to maintain the first and second edge assemblies at a fixed distance apart; each of the first and second fabric panels is woven from fibers that extend in both the longitudinal and lateral directions, wherein the edge assemblies are disposed at the ends of the fibers that extend in the longitudinal direction; and each of the first and second fabric panels is woven from fibers that extend in both the longitudinal and lateral directions, wherein the edge assemblies are disposed at the ends of the fibers that extend in the lateral direction.

Broadly defined, the present invention according to another aspect is an electricity-generating fabric panel unit, including: a panel of light-collecting fabric produced at least partly from optical waveguides, each waveguide including: an active core hosting material configured to absorb, emit and transmit light, a cladding layer surrounding the active core, the cladding layer being configured to allow ambient light to pass through the cladding layer, and an exit port located proximate an end of the waveguide; and an edge assembly disposed along an edge of the fabric panel and adapted to collect light from the exit ports of the fiber optical waveguides of the fabric panel and convert it to electricity.

In a feature, an electricity-generating fabric panel unit where the panel of light-collecting fabric is produced from a combination of optical waveguides and a conformal composite material; the housing includes two case sections attached on opposite surfaces of the fabric panel; a photovoltaic interface is disposed within the housing; the photovoltaic interface includes a strip of photovoltaic cells disposed to receive light directly from exit ports of the optical waveguides; the housing defines an interior cavity, and where the strip of photovoltaic cells is supported by a wall structure disposed within the interior cavity at a distance from the lateral walls of the cavity; the photovoltaic interface includes two strips of photovoltaic cells, each strip being angled relative to the path of light received from the exit ports of the optical waveguides, and also being angled relative to each other; an electrical connector is electrically connected to an output of the photovoltaic interface; and the electrical connector is at least partly disposed within the housing.

In a further feature, an electricity-generating fabric panel unit where the edge assembly includes a hinge structure for hingedly coupling the panel unit to another object having a complementary hinge structure; the hinge structure includes a portion of a barrel hinge; the hinge structure includes a portion of a clevis hinge; the hinge structure is a first hinge structure, and wherein the edge assembly includes a second separate, spaced-apart hinge structure for hingedly coupling the panel unit to an object having a complementary hinge structure; the first hinge structure is adapted for hingedly coupling the panel unit to a first object, and wherein the second hinge structure is adapted for hingedly coupling the panel unit to a second object; the first and second hinge structures are each adapted for hingedly coupling the panel unit to the same object; the first and second hinge structures are each located along a side of the edge assembly; and the first hinge structure is disposed at a first end of the edge assembly and extends in a first direction, where the second hinge structure is disposed at a second, opposite end of the edge assembly and extends in a second direction, and wherein the first and second directions are substantially opposite each other.

In a further feature, an electricity-generating fabric panel unit where the edge assembly is a first edge assembly disposed along a first edge of the fabric panel, wherein the panel unit further comprises a second edge assembly disposed along a second edge of the fabric panel and adapted to collect light from the fabric panel and convert it to electricity, and wherein the first and second edges of the fabric panel are opposite each other; the fabric panel is stretched between the first and second edge assemblies; and the first and second edge assemblies are connected by a rigid bridge to maintain the first and second edge assemblies at a fixed distance apart.

Broadly defined, the present invention according to another aspect is an electricity-generating fabric panel unit, including: a panel of light-collecting fabric produced at least partly from optical waveguides, each waveguide including: a passive core hosting material configured to transmit light, an active cladding hosting material surrounding the passive core and configured to absorb and emit light, and an exit port located proximate an end of the waveguide; and an edge assembly disposed along an edge of the fabric panel and adapted to collect light from the exit ports of the optical waveguides of the fabric panel and convert it to electricity.

In a feature, an electricity-generating fabric panel unit where the panel of light-collecting fabric is produced from a combination of optical waveguides and a conformal composite material; the housing includes two case sections attached on opposite surfaces of the fabric panel; a photovoltaic interface is disposed within the housing; the photovoltaic interface includes a strip of photovoltaic cells disposed to receive light directly from exit ports of the optical waveguides; the housing defines an interior cavity, and where the strip of photovoltaic cells is supported by a wall structure disposed within the interior cavity at a distance from the lateral walls of the cavity; the photovoltaic interface includes two strips of photovoltaic cells, each strip being angled relative to the path of light received from the exit ports of the optical waveguides, and also being angled relative to each other; an electrical connector is electrically connected to an output of the photovoltaic interface; and the electrical connector is at least partly disposed within the housing.

In a further feature, an electricity-generating fabric panel unit where the edge assembly includes a hinge structure for hingedly coupling the panel unit to another object having a complementary hinge structure; the hinge structure includes a portion of a barrel hinge; the hinge structure includes a portion of a clevis hinge; the hinge structure is a first hinge structure, and wherein the edge assembly includes a second separate, spaced-apart hinge structure for hingedly coupling the panel unit to an object having a complementary hinge structure; the first hinge structure is adapted for hingedly coupling the panel unit to a first object, and wherein the second hinge structure is adapted for hingedly coupling the panel unit to a second object; the first and second hinge structures are each adapted for hingedly coupling the panel unit to the same object; the first and second hinge structures are each located along a side of the edge assembly; and the first hinge structure is disposed at a first end of the edge assembly and extends in a first direction, where the second hinge structure is disposed at a second, opposite end of the edge assembly and extends in a second direction, and wherein the first and second directions are substantially opposite each other.

In a further feature, an electricity-generating fabric panel unit where the edge assembly is a first edge assembly disposed along a first edge of the fabric panel, wherein the panel unit further comprises a second edge assembly disposed along a second edge of the fabric panel and adapted to collect light from the fabric panel and convert it to electricity, and wherein the first and second edges of the fabric panel are opposite each other; the fabric panel is stretched between the first and second edge assemblies; and the first and second edge assemblies are connected by a rigid bridge to maintain the first and second edge assemblies at a fixed distance apart.

Broadly defined, the present invention according to another aspect is an umbrella-type sunshade for generating electricity, including: a support pole; a center top assembly coupled to the support pole; a plurality of ribs extending radially from the center top assembly; a panel of light-collecting fabric extending between adjacent ribs of the plurality of ribs; and a photovoltaic interface disposed along a first of the adjacent ribs and adapted to collect light from the fabric panel and convert it to electricity.

In a feature, the panel of light-collecting fabric is produced at least partly from flexible optical waveguides; the photovoltaic interface is disposed in an interior of the first of the adjacent ribs; a panel of light-collecting fabric extends between each pair of adjacent ribs of the plurality of ribs; the photovoltaic interface is electrically connected to wiring extending up through the rib in whose interior the photovoltaic interface is disposed to the center top assembly; the center top assembly is electrically connected to wiring in the support pole; the wiring in the center top assembly is electrically connected to a battery; a base for retaining a lower end of the support pole, and wherein the battery is disposed within the base; a power outlet is electrically connected to the battery; where the power outlet is disposed along the length of the support pole; the power outlet is disposed within an outlet box attached to the support pole intermediate an upper end of the pole and the lower end of the pole; where the power outlet provides standard household electricity.

In further feature, the photovoltaic interface is a first photovoltaic interface, and wherein the sunshade further comprises a second photovoltaic interface disposed in an interior of a second of the adjacent ribs and adapted to collect light from the fabric panel and convert it to electricity.

In further feature, the photovoltaic interface is a first photovoltaic interface and the rib in whose interior it is disposed is a first rib, wherein the panel of light-collecting fabric is a first panel of light-collecting fabric extending between the first rib and a second rib, wherein the sunshade further comprises a second panel of light-collecting fabric extending between the first rib and a third rib that is adjacent to the first rib, and wherein the sunshade further comprises a second photovoltaic interface disposed in the interior of the first rib and adapted to collect light from the second fabric panel and convert it to electricity.

Broadly defined, the present invention according to another aspect is a method of powering an electrical device using an umbrella-type sunshade, including: providing an umbrella-type sunshade, including a center assembly, a pair of adjacent ribs extending radially from the center assembly, a panel of light-collecting fabric extending between the adjacent ribs, and a photovoltaic interface disposed within at least one of the adjacent ribs and adapted to collect light from the fabric panel and convert it to electrical energy; receiving sunlight at the panel of light-collecting fabric extending between the adjacent ribs; guiding the sunlight within the fabric panel to at least one of the adjacent ribs; converting the sunlight to electrical energy via the photovoltaic interface disposed within the at least one of the adjacent ribs; using the electrical energy to provide electricity to a power outlet connected to the umbrella-type sunshade; and providing the electricity from the power outlet to an electrical device plugged into the power outlet.

In further method, of providing an umbrella-type sunshade includes providing an umbrella-type sunshade that includes a support pole, and wherein the center assembly is a center top assembly that is coupled to the support pole; of providing an umbrella-type sunshade that includes a support pole includes providing an umbrella-type sunshade that includes a support pole having the power outlet disposed along its length; of providing an umbrella-type sunshade includes providing a battery, and wherein providing an umbrella-type sunshade that includes a support pole having the power outlet disposed along its length includes providing an umbrella-type sunshade whose power outlet is electrically connected to the battery; where after converting the sunlight to electrical energy via the photovoltaic interface, converting the electrical energy to chemical energy and storing the chemical energy in the battery; thereafter, converting the chemical energy to electrical energy for use in the step of providing electricity to the power outlet.

Broadly defined, the present invention according to another aspect is an electricity-generating device as shown and described.

Broadly defined, the present invention according to another aspect is a multi-unit electricity-generating device as shown and described.

Broadly defined, the present invention according to another aspect is an electricity-generating fabric panel unit as shown and described.

Broadly defined, the present invention according to another aspect is a multi-unit electricity-generating device comprising a plurality of electricity-generating fabric panel units as shown and described.

Broadly defined, the present invention according to another aspect is a method of generating electricity as shown and described.

Broadly defined, the present invention according to another aspect is a method of powering an electrical device using an umbrella-type sunshade, as shown and described.

Further areas of applicability of the present invention will become apparent from the detailed description provided hereinafter. It should be understood that the detailed description and specific examples, while indicating the preferred embodiment of the invention, are intended for purposes of illustration only and are not intended to limit the scope of the invention.

### BRIEF DESCRIPTION OF THE DRAWINGS

Further features, embodiments, and advantages of the present invention will become apparent from the following detailed description with reference to the drawings, wherein:

FIG. 1 is an isometric view of a series of electricity-generating fabric panel units connected together in accordance with one or preferred embodiments of the present invention;

FIG. 2 is an isometric view of one of the panel units of FIG. 1;

FIG. 3 is a schematic top view of a portion of the fabric panel of FIG. 2;

FIG. 4 is a top plan view of the panel unit of FIG. 2;

FIG. 5A is an isometric view of the panel unit of FIG. 2, shown cut away along line 5-5;

FIG. 5B is an enlarged fragmentary view of a portion of the panel unit of FIG. 5A;

FIG. 6 is a fragmentary end cross-sectional view of a portion of the panel unit of FIG. 2, taken along line 5-5;

FIG. 7 is an isometric view of an alternative panel unit in accordance with one or more preferred embodiments of the present invention;

FIG. 8 is a top plan view of the panel unit of FIG. 7;

FIG. 9 is an isometric view of the panel unit of FIG. 7, shown cut away along line 9-9;

FIG. 10 is a fragmentary end cross-sectional view of a portion of the panel unit of FIG. 7, taken along line 9-9;

FIG. 11 is a front orthogonal view of a pair of the alternative panel units of FIGS. 7-10, shown linked together via their hinge structures, with hinge pins (not visible) inserted used to hold the hinge structures together;

FIG. 12 is a perspective view of an electricity-generating umbrella-type sunshade in accordance with one or more preferred embodiments of the present invention;

FIG. 13 is an enlarged fragmentary perspective view of a portion of the pole of FIG. 12, showing an integral outlet box mounted to the pole; and

FIG. 14 is a perspective view of the electricity-generating umbrella-type sunshade of FIG. 12 installed in a conventional center-hole patio table.

### DETAILED DESCRIPTION

As a preliminary matter, it will readily be understood by one having ordinary skill in the relevant art (“Ordinary Artisan”) that the present invention has broad utility and application. Furthermore, any embodiment discussed and identified as being “preferred” is considered to be part of a best mode contemplated for carrying out the present invention. Other embodiments also may be discussed for additional illustrative purposes in providing a full and enabling disclosure of the present invention. As should be understood, any embodiment may incorporate only one or a plurality of the above-disclosed aspects of the invention and may further incorporate only one or a plurality of the above-disclosed features. Moreover, many embodiments, such as adaptations, variations, modifications, and equivalent arrangements, will be implicitly disclosed by the embodiments described herein and fall within the scope of the present invention.

Accordingly, while the present invention is described herein in detail in relation to one or more embodiments, it is to be understood that this disclosure is illustrative and exemplary of the present invention, and is made merely for the purposes of providing a full and enabling disclosure of the present invention. The detailed disclosure herein of one or more embodiments is not intended, nor is to be construed, to limit the scope of patent protection afforded the present invention, which scope is to be defined by the claims and the equivalents thereof It is not intended that the scope of patent protection afforded the present invention be defined by reading into any claim a limitation found herein that does not explicitly appear in the claim itself.

Thus, for example, any sequence(s) and/or temporal order of steps of various processes or methods that are described herein are illustrative and not restrictive. Accordingly, it should be understood that, although steps of various processes or methods may be shown and described as being in a sequence or temporal order, the steps of any such processes or methods are not limited to being carried out in any particular sequence or order, absent an indication otherwise. Indeed, the steps in such processes or methods generally may be carried out in various different sequences and orders while still falling within the scope of the present invention. Accordingly, it is intended that the scope of patent protection afforded the present invention is to be defined by the appended claims rather than the description set forth herein.

Additionally, it is important to note that each term used herein refers to that which the Ordinary Artisan would understand such term to mean based on the contextual use of such term herein. To the extent that the meaning of a term used herein—as understood by the Ordinary Artisan based on the contextual use of such term—differs in any way from any particular dictionary definition of such term, it is intended that the meaning of the term as understood by the Ordinary Artisan should prevail.

Regarding applicability of 35 U.S.C. §112, ¶6, no claim element is intended to be read in accordance with this statutory provision unless the explicit phrase “means for” or “step for” is actually used in such claim element, whereupon this statutory provision is intended to apply in the interpretation of such claim element.

Furthermore, it is important to note that, as used herein, “a” and “an” each generally denotes “at least one,” but does not exclude a plurality unless the contextual use dictates otherwise. Thus, reference to “a picnic basket having an apple” describes “a picnic basket having at least one apple” as well as “a picnic basket having apples.” In contrast, reference to “a picnic basket having a single apple” describes “a picnic basket having only one apple.”

When used herein to join a list of items, “or” denotes “at least one of the items,” but does not exclude a plurality of items of the list. Thus, reference to “a picnic basket having cheese or crackers” describes “a picnic basket having cheese without crackers,” “a picnic basket having crackers without cheese,” and “a picnic basket having both cheese and crackers.” Finally, when used herein to join a list of items, “and” denotes “all of the items of the list.” Thus, reference to “a picnic basket having cheese and crackers” describes “a picnic basket having cheese, wherein the picnic basket further has crackers,” as well as describes “a picnic basket having crackers, wherein the picnic basket further has cheese.”

Referring now to the drawings, in which like numerals represent like components throughout the several views, one or more preferred embodiments of the present invention are next described. The following description of one or more preferred embodiment(s) is merely exemplary in nature and is in no way intended to limit the invention, its application, or uses.

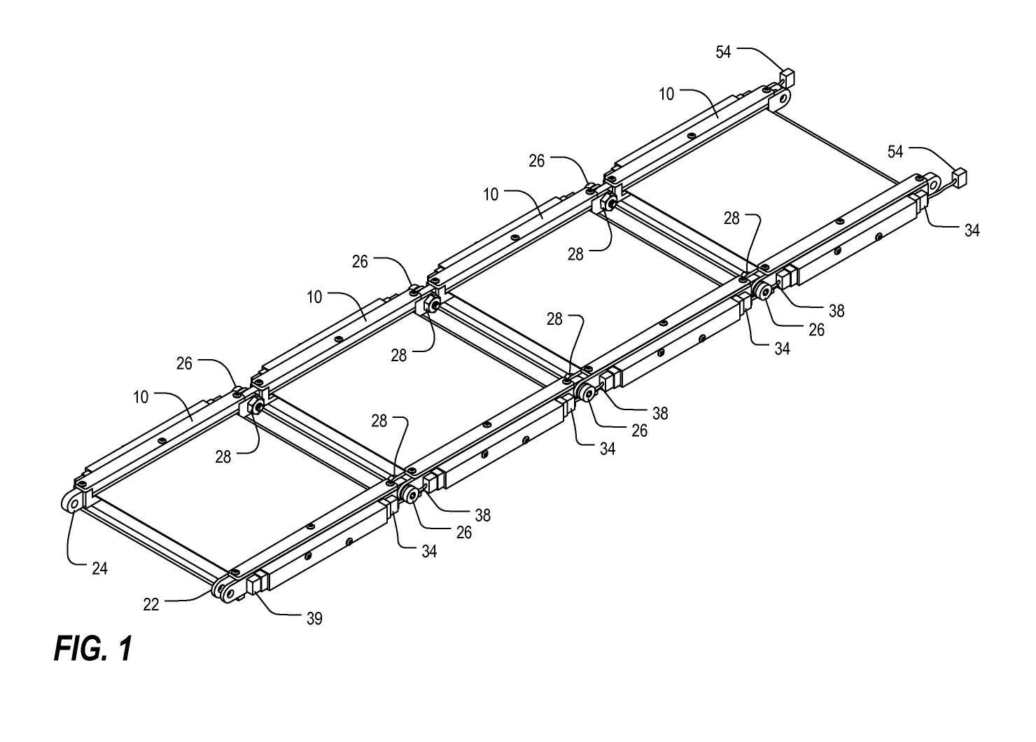

FIG. 1 is an isometric view of a series of electricity-generating fabric panel units 10 connected together in accordance with one or preferred embodiments of the present invention. As shown therein, any number of panel units 10 may be connected together via hinge structures disposed along opposite sides of each unit 10. The panel units 10 are described in greater detail hereinbelow.

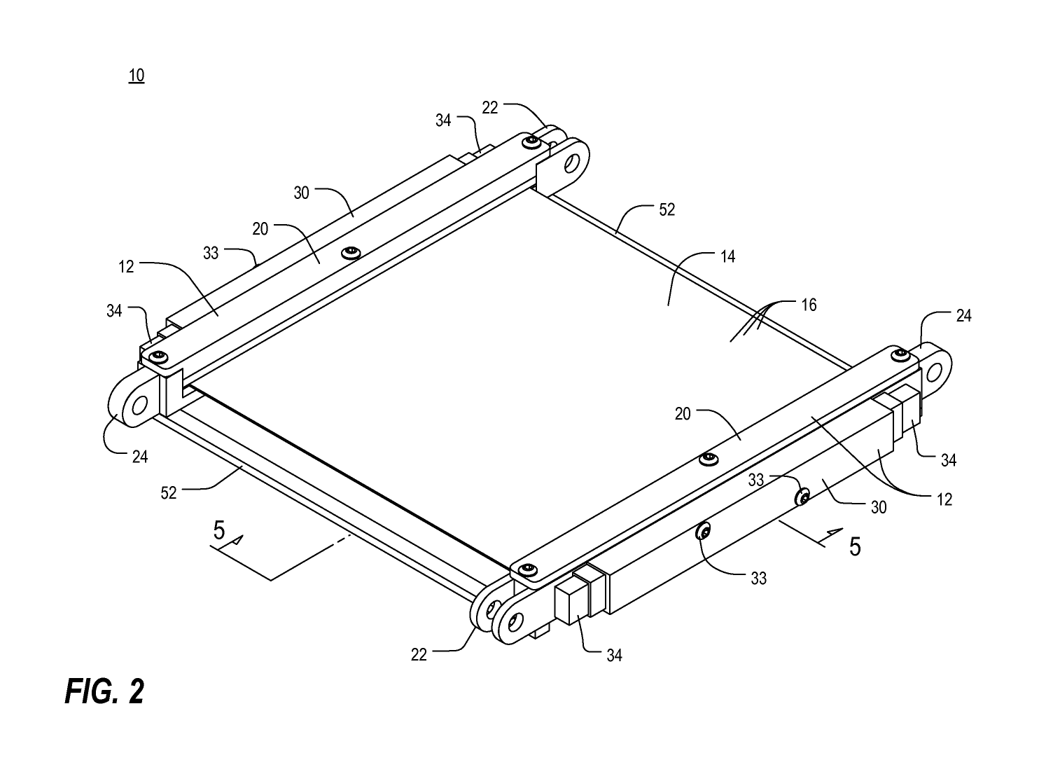

FIG. 2 is an isometric view of one of the panel units 10 of FIG. 1. As shown therein, the panel unit 10 includes a pair of edge assemblies 12 disposed along opposite edges of a panel of light-collecting fabric 14. The light-collecting fabric is woven or otherwise constructed from flexible optical waveguides 16 that collect ambient light and redirects it along its length to one or both of its ends, at least some of which terminate within the edge assemblies 12. Optical waveguides suitable for use in one or more preferred embodiments of the present invention are disclosed in Farahi U.S. nonprovisional patent application Ser. No. 12/853,867, filed Aug. 10, 2010, which nonprovisional patent application published Sep. 29, 2011 as U.S. patent application publication no. 2011/0232211, which patent application and publication are incorporated by reference herein.

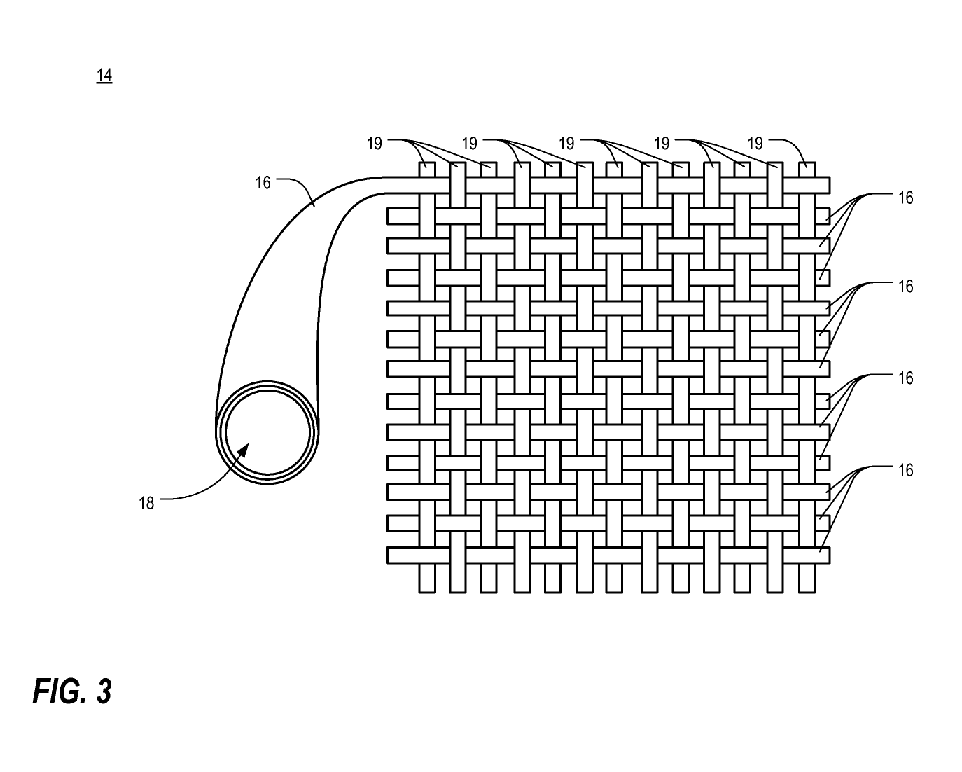

FIG. 3 is a schematic top view of a portion of the fabric panel 14 of FIG. 2. As shown therein, fiber optical waveguides 16 have been woven using generally conventional textile weaving techniques into a piece of fabric. In this particular panel 14, the fiber optical waveguides 16 are used in only one (longitudinal or lateral) direction, with conventional fibers 19, such as of wool, cotton, nylon, polyester or other materials, being used in the other (lateral or longitudinal, respectively) direction. It will be appreciated, however, that in at least some embodiments, fiber optical waveguides 16 could be used in both directions, and that fiber optical waveguides 16 may be used in or with conformal composites like fiberglass, carbon fiber, aramid synthetic fiber (such as Kevlar®), and the like. Furthermore, it will be appreciated that fiber optical waveguides 16 could be interspersed with other fibers, that fiber optical waveguides 16 could be used only in portions of a particular fabric, and that many other arrangements are possible. These different arrangements may be selected to achieve desired goals in fabric strength, durability, resiliency, water resistance, and the like.

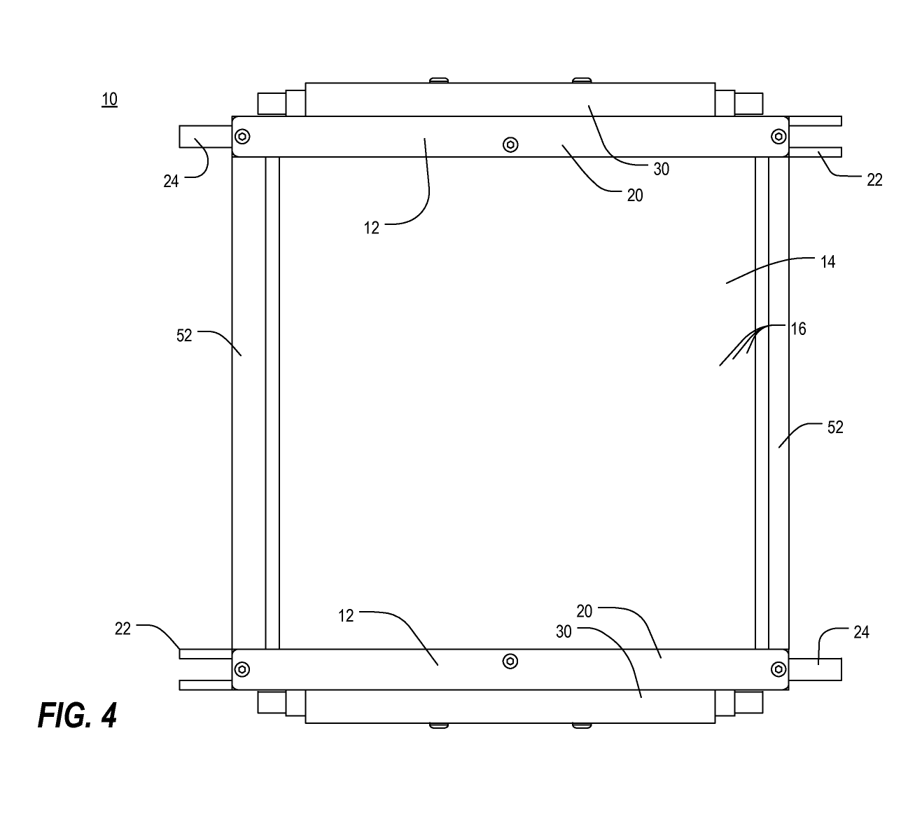

FIG. 4 is a top plan view of the panel unit 10 of FIG. 2. Referring to both FIGS. 2 and 4, each edge assembly 12 includes a base 20 and an electrical collector 30 attached via fasteners 33 or other attachment means. A hinge structure 22,24 is disposed at each end of each base 20. In the embodiment shown in FIGS. 2-6, a clevis 22 extends from one end of each base 20 and a tang 24 extends from the opposite end; however, it will be appreciated that other types of hinge structures may likewise be utilized. In at least some embodiments, the two bases 20 are oriented such that the clevis 22 of one base 20 is aligned with the tang 24 of the other base 20, and vice versa. However, other arrangements are likewise possible.

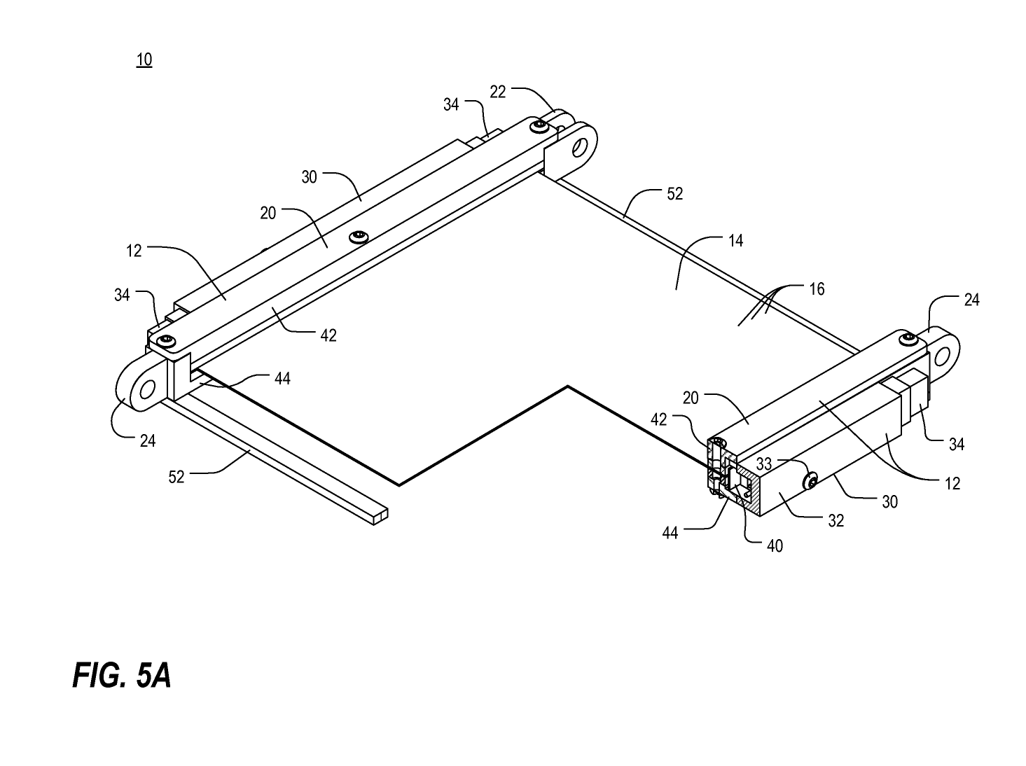

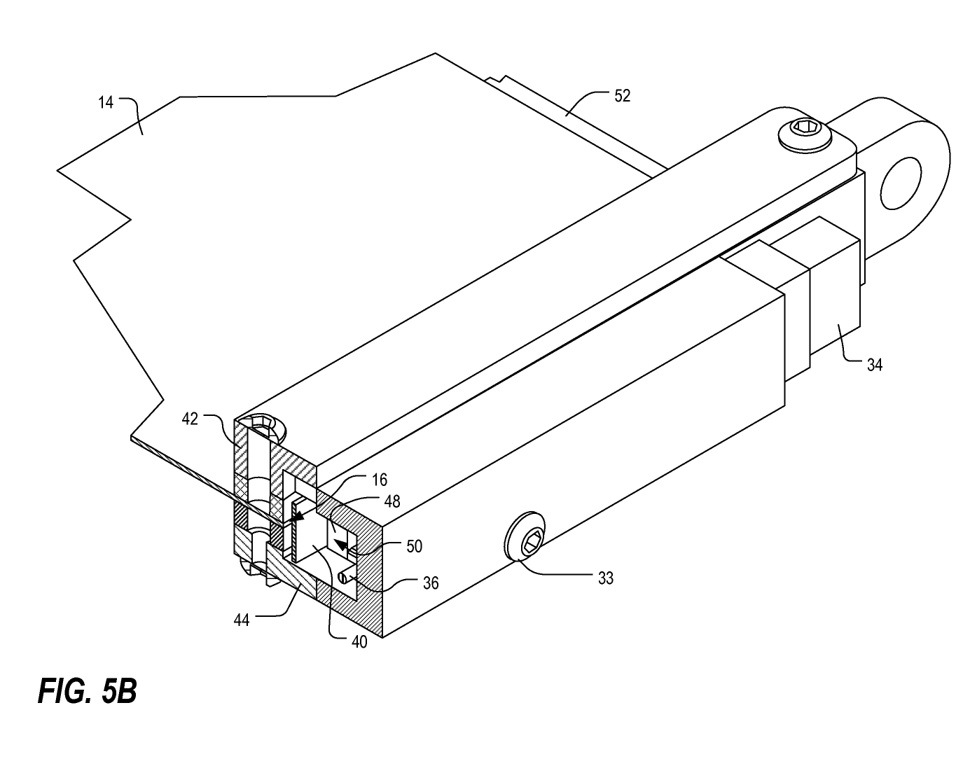

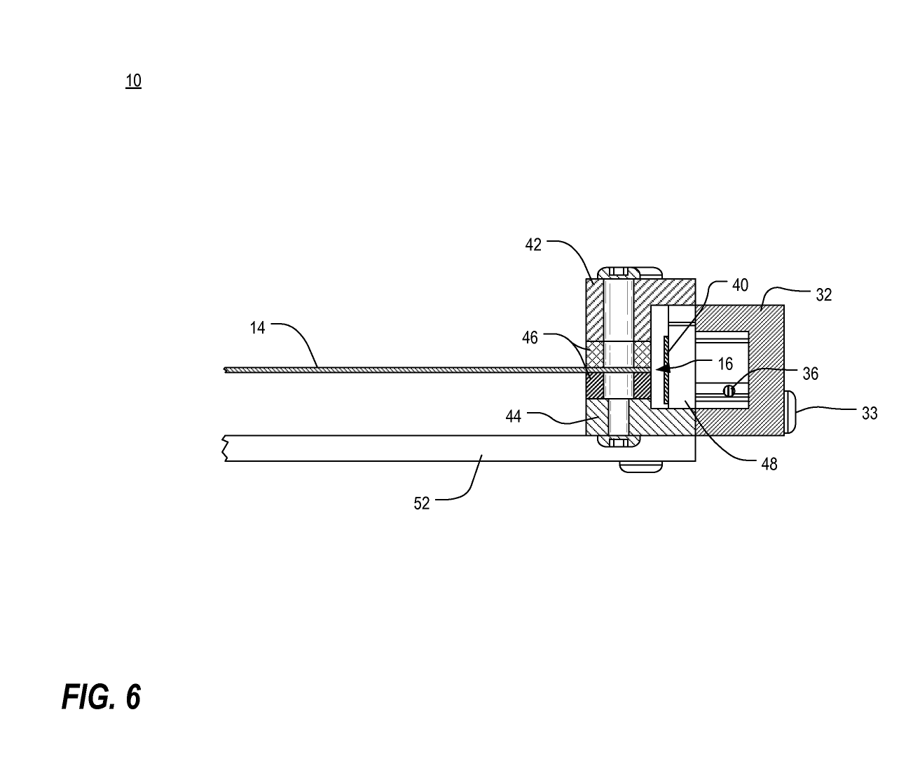

FIG. 5A is an isometric view of the panel unit 10 of FIG. 2, shown cut away along line 5-5, FIG. 5B is an enlarged fragmentary view of a portion of the panel unit 10 of FIG. 5A, and FIG. 6 is a fragmentary end cross-sectional view of a portion of the panel unit 10 of FIG. 2, taken along line 5-5. The electrical collector 30 includes a collector housing 32 supporting a pair of external electrical connectors 34 that are electrically connected to one another by appropriate wiring 36 running inside the housing 32. In at least some embodiments, each electrical connector 34 is a male connector. Each connector 34 may either be linked to a connector 34 on another panel unit 10, such as via a short jumper cable 38, or may be left unused. In the latter case, a dummy plug 39, which may be a shorted plug, may be connected to the connector 34 to render the connector 34 inoperable and/or protect it from short-circuiting and the like.

As perhaps best seen in FIGS. 5B and 6, a photovoltaic interface 40 receives light from the optical waveguides 16, converts it to electricity, and feeds the electricity to the electrical connectors 34 for transmission elsewhere. In at least some embodiments, the photovoltaic interface 40 is a strip of photovoltaic cells (sometimes referred to as a “solar ribbon”) that is disposed along the exit ports 18 of the optical waveguides 16 and is electrically coupled to the electrical connectors 34. The optical waveguides 16 of the fabric panel 14 capture ambient light and guide it along their interiors to their exit ports 18, where it is directed toward the solar ribbon 40. The photovoltaic cells of the solar ribbon 40 convert the light to electrical energy which is transferred elsewhere, such as to a mobile electronic device.

Each end segment base 20 is a housing that includes upper and lower case sections 42,44 clamped or otherwise attached along the edge of the fabric panel 14. In order to prevent damage to the fabric panel 14 and to protect the photovoltaic interface 40 from the outside environment, gasketing material 46 is attached along the edge of the fabric panel 14, between the two case sections 42,44. In at least some embodiments, the gasketing material 46 is foam that is bonded to the fabric panel with epoxy, but in other embodiments, the gasketing material 46 could be anything from a visco-elastic material to a hard plastic, and it could be fastened to the fabric panel 14 in some other way. A ribbon wall 48, which in at least some embodiments may be a portion of one of the case sections 42,44, is disposed at a small distance from the ends of the optical waveguides 16 and supports the photovoltaic interface 40. In the embodiment shown, the ribbon wall 48 is a portion of the bottom base piece 44. One or more window openings 50 in the ribbon wall 48 provide access from the photovoltaic interface 40 to the interior of the collector housing 32, thereby permitting electrical connections to be made to/from the solar ribbon 40.

In at least some embodiments, including the one of FIGS. 2-6, the two edge assemblies 12 of each panel unit 10 are connected together via a pair of bridge ties or struts 52. The bridges 52 may reduce tension on the fabric panel 14, retain the fabric panel 14 in a fully stretched arrangement, or both. The bridges 52 may be attached to the edge assemblies 12 using the same fasteners or fastening system that are or is used to hold the case sections 42,44 clamped around the fabric panel 14 and gasketing material 46.

Returning to FIG. 1, four panel units 10 are shown linked together via their devises 22 and tangs 24, with clevis pins 26 and corresponding nuts 28 used to hold them together. The electrical connectors 34 along one side of the linked panel units 10 are linked together with appropriate wiring, with a dummy plug 39 or the like attached at one end and a connector cable and plug 54 being provided at the other end. The electrical connectors along the other side of the linked panel units 10 are similarly linked together.

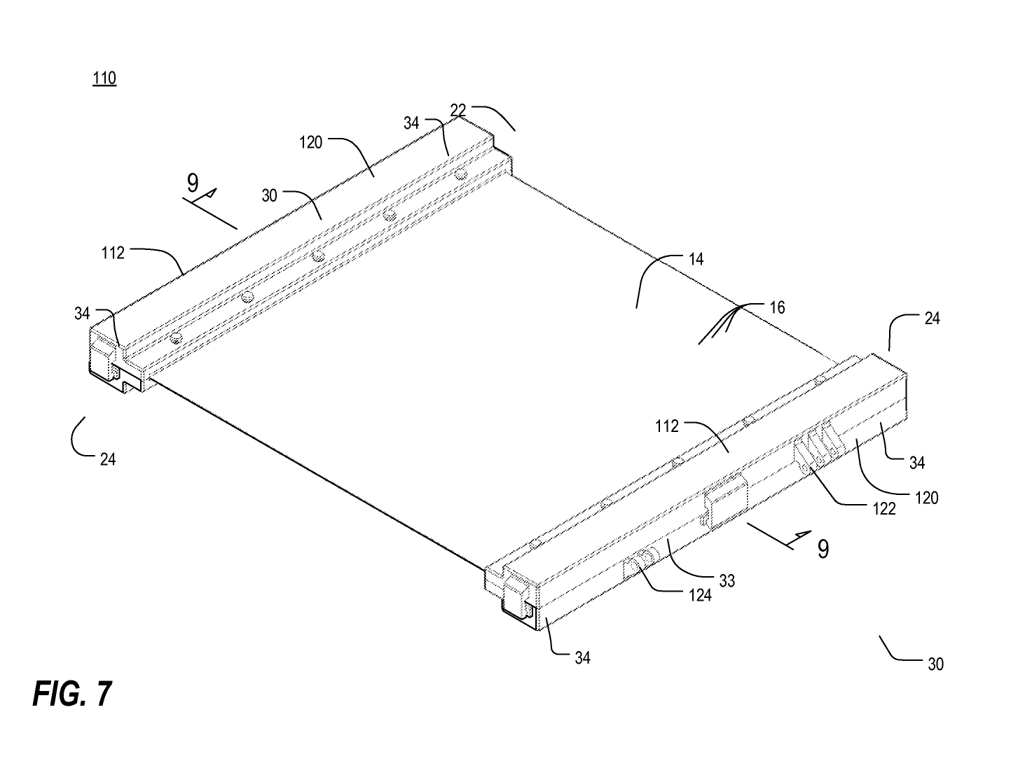

FIG. 7 is an isometric view of an alternative panel unit 110 in accordance with one or more preferred embodiments of the present invention. As shown therein, the panel unit 110 includes a pair of edge assemblies 112 disposed along opposite edges of a panel of light-collecting fabric 14 similar to that of FIGS. 2-6 in that it is woven or otherwise constructed from optical waveguides 16 that collect ambient light and redirects it along its length to one or both of its ends, at least some of which terminate within the edge assemblies 112.

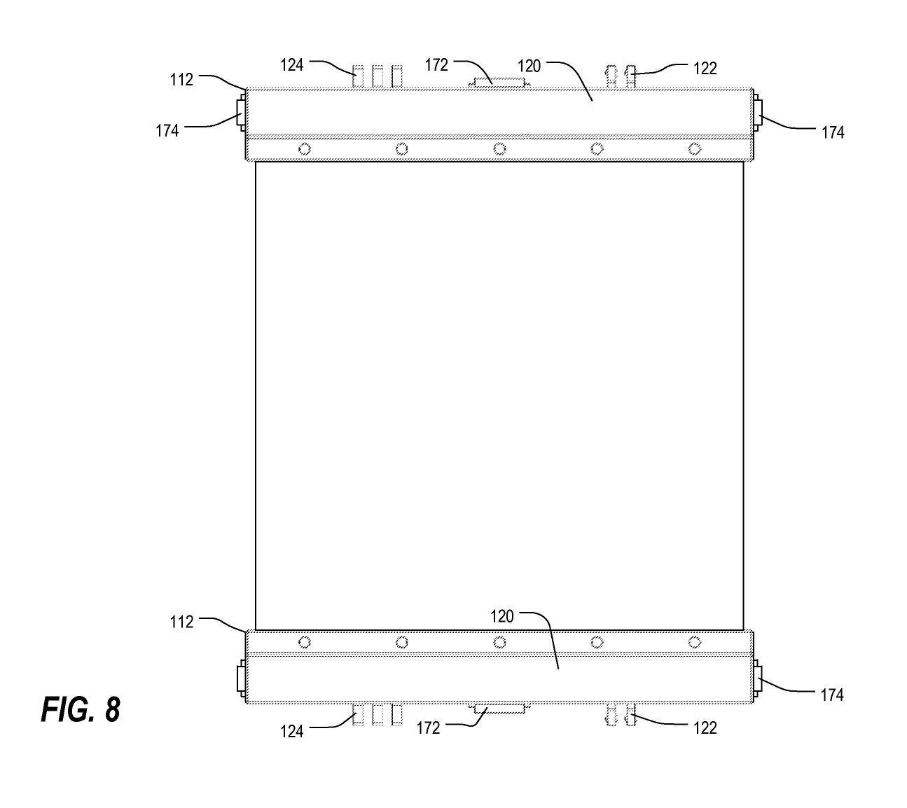

FIG. 8 is a top plan view of the panel unit 110 of FIG. 7. Referring to both FIGS. 7 and 8, each assembly 112 includes a housing 120 having one or more hinge structures are disposed along it. In the embodiment shown in FIGS. 7-10, two multi-loop hinge structures 122,124 are disposed along each edge assembly 112, with one hinge structure 122 utilizing two loops and the other hinge structure 124 utilizing three. However, it will be appreciated that other types of hinge structures may likewise be utilized. Furthermore, in at least some embodiments, the hinge structures are complementary, such that one hinge structure on one of the edge assemblies may be coupled to a complementary hinge structure on another object, such as another panel unit 110. In this regard, it will be appreciated that the two-loop hinge structure 122 and the three-loop hinge structure 124 are complementary in that each may be mated with a corresponding hinge structure 124,122 (i.e., two-loop to three-loop and three-loop to two-loop) on another panel unit 110 and linked via hinge pins, as further described hereinbelow. However, other arrangements are likewise possible.

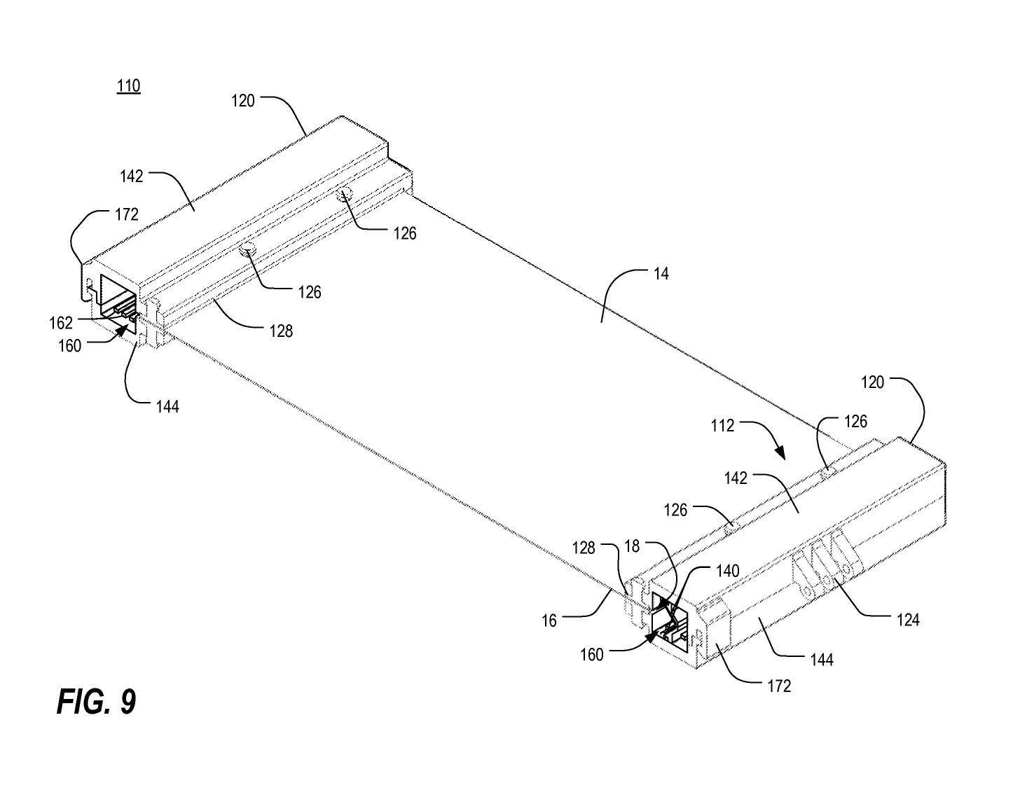

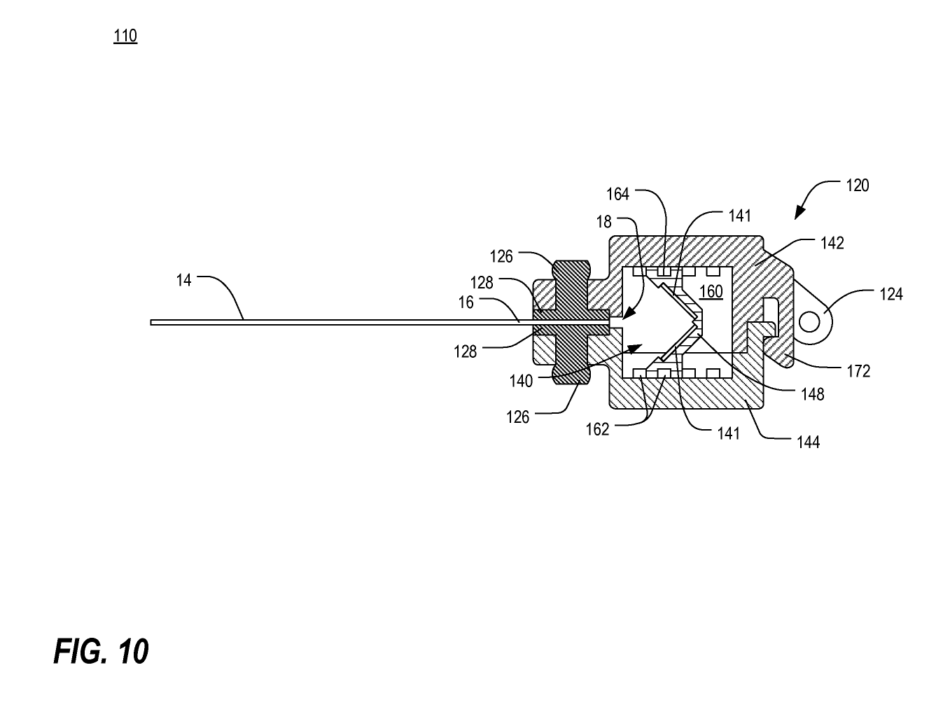

FIG. 9 is an isometric view of the panel unit 110 of FIG. 7, shown cut away along line 9-9, and FIG. 10 is a fragmentary end cross-sectional view of a portion of the panel unit 110 of FIG. 7, taken along line 9-9. As shown therein, each housing 120 includes upper and lower case sections 142,144 attached along the edge of the fabric panel 14 and defining an interior cavity 160. A photovoltaic interface 140 receives light from the optical fiber waveguides 16 and converts it to electricity which may be fed to electrical connectors (not shown) disposed within and/or extending from the edge assembly 112. In at least some embodiments, the photovoltaic interface 140 includes two strips of photovoltaic cells (each sometimes referred to as a “solar ribbon”) 141 that are disposed along the exit ports 18 of the optical waveguides 16 and are electrically coupled to the electrical connectors. In the arrangement shown, one solar ribbon 141 is disposed at an upwardly-angled 45-degree angle along the bottom of the interior cavity 160, and another solar ribbon 141 is disposed at a downwardly-angled 45-degree angle along the top of the interior cavity 160. The optical waveguides 16 of the fabric panel 14 capture ambient light and guide it along their interiors to their exit ports 18, where it is directed toward the solar ribbons 141. The photovoltaic cells of the solar ribbons 141 convert the light to electrical energy which is transferred elsewhere, such as to a mobile electronic device.

Although not illustrated, in order to prevent damage to the fabric panel 14 and to protect the photovoltaic interface 40 from the outside environment, gasketing material may be attached along the edge of the fabric panel 14, between the two case sections 142,144. The gasketing material may be constructed and/or attached in any of the ways described previously.

The upper and lower case sections 142,144 are held together along one lengthwise side and at their ends by hook snaps 172,174, and along the other lengthwise side by posts 126 extending from a strip 128 that is glued or otherwise attached to the fabric panel 14, as perhaps best seen in FIG. 10. In at least some embodiments a separate post strip 128 is provided on each surface of the fabric panel 14. A head on each post 126 is inserted through a corresponding opening in the corresponding case section 142,144 and snaps in place. Alternatively, each post may be threaded and fastened using nuts or other fasteners.

A ribbon wall 148 is disposed at a relatively small distance from the ends of the optical waveguides 16 and supports the photovoltaic interface 40. In the embodiment shown, the ribbon wall 148 is an elongated repositionable structure having an upwardly-angled support surface at the bottom and a downwardly-angled support surface at the top. Each support surface is adapted to receive and support one of the solar ribbons 141.

In at least some embodiments, a plurality of ridges 162 are disposed along the bottom surface and top surface of the interior cavity 160 of the edge assembly 112. The ridges 162 serve as teeth and are adapted to mate with grooves 164 in the top and bottom portions of the ribbon wall 148. If desired, the ribbon wall 148 may be repositioned by opening the housing 120, removing the ribbon wall 148 from its position along one of the ridges 162 and repositioning it along a different ridge 162. This may be useful at least for testing purposes.

In at least some embodiments, the two edge assemblies 112 of each panel unit 110 may connected together via a pair of bridge ties or struts (not shown) similar to those of the embodiment shown in FIGS. 2-6.

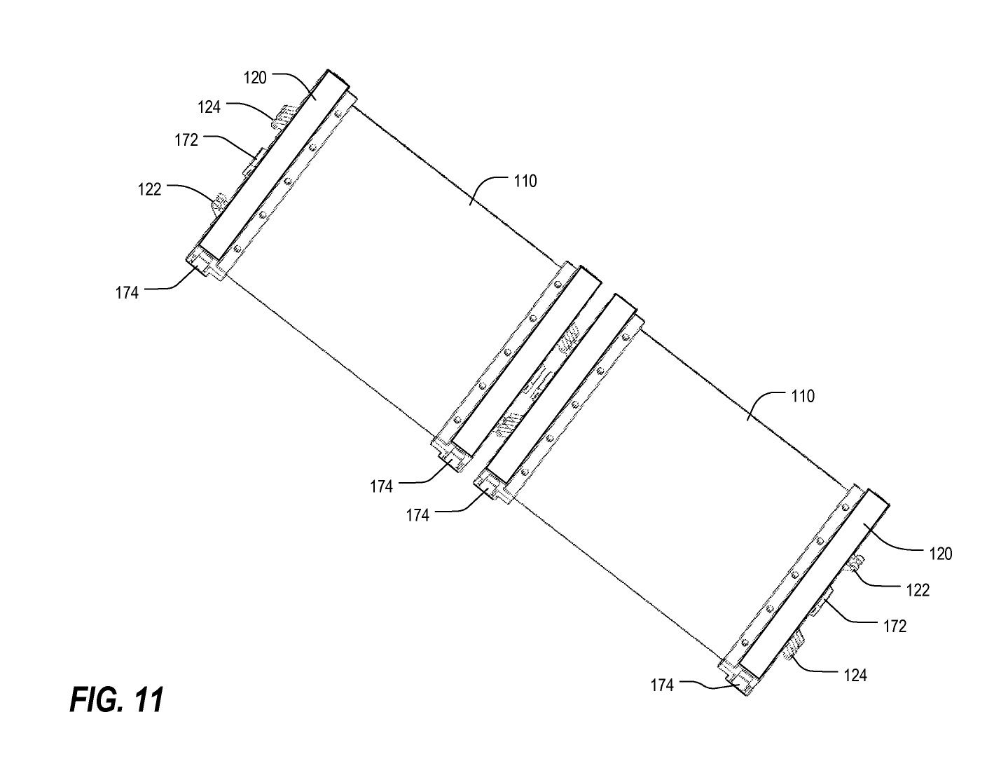

FIG. 11 is a front orthogonal view of a pair of the alternative panel units 110 of FIGS. 7-10, shown linked together via their hinge structures 122,124, with hinge pins (not visible) inserted used to hold the hinge structures 122,124 together. As with the arrangement of FIG. 1, the electrical connectors along one side of the linked panel units 110 may be linked together with appropriate wiring, with dummy plugs and connector cables and plugs (not shown) used as appropriate.

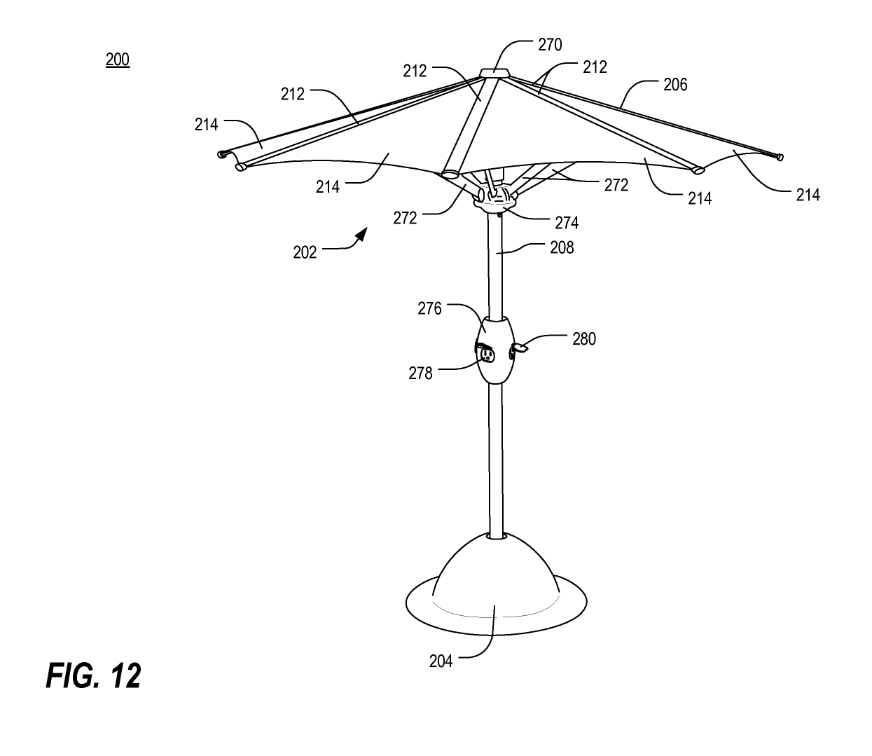

FIG. 12 is a perspective view of an electricity-generating umbrella-type sunshade 200 in accordance with one or more preferred embodiments of the present invention. The sunshade includes an umbrella 202 and a base 204. The umbrella 202 includes an umbrella-type shade 206 and a support pole 208 that may be retained in a standing position in the base 204. The support pole 208 is preferably at least partially hollow such that wiring may be contained therein. The shade 206 includes a plurality of ribs or battens 212 between which are stretched a corresponding number of light-collecting fabric panels 214. The fabric panels 214 may be constructed similarly to the panels 14 of FIGS. 2-6 in that it is woven or otherwise constructed from optical waveguides 16 that collect ambient light and redirects it along its length to one or both of its ends, at least some of which terminate within the battens 212. In this respect, the battens 212 are similar in form and function to the edge assemblies 12,112 of FIGS. 2-6 and 7-10, respectively.

Each batten 212 at its proximal end by a central top assembly 270 and at its distal end by a respective stretcher 272 which is in turn supported by a runner 274. Each batten 212 may include one or more case pieces that define an interior cavity (not shown). Similar to the construction of the edge assemblies 12,112 of FIGS. 2-6 and 7-10 described previously, a photovoltaic interface (not shown) may be arranged to receive light from the optical waveguides 16 and convert it to electricity which may be fed to electrical connectors (not shown) disposed within and/or extending from the battens 212. In at least some embodiments, the photovoltaic interface includes one or more strips of photovoltaic cells (each sometimes referred to as a “solar ribbon”) that are disposed along the exit ports 18 of the optical waveguides 16 and are electrically coupled to the electrical connectors. The optical waveguides 16 of each fabric panel 214 capture ambient light and guide it along their interiors to their exit ports 18, where it is directed toward the solar ribbons in the battens or edge assemblies 212. The photovoltaic cells of the solar ribbons convert the light to electrical energy which is transferred up through the battens 212 to the top assembly 270 of the umbrella 202, and from there down through the hollow support pole 208.

Although not illustrated, in order to prevent damage to the fabric panel 214 and to protect the photovoltaic interface from the outside environment, gasketing material may be attached along the edge of the fabric panel 214 where it enters the battens 212. The gasketing material may be constructed and/or attached to the fabric panel 214 in any of the ways described previously.

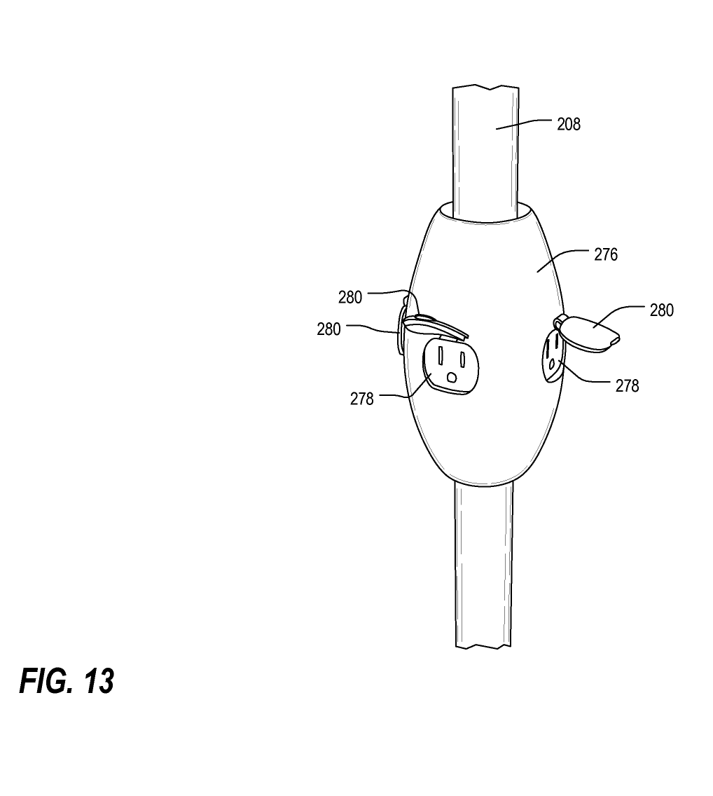

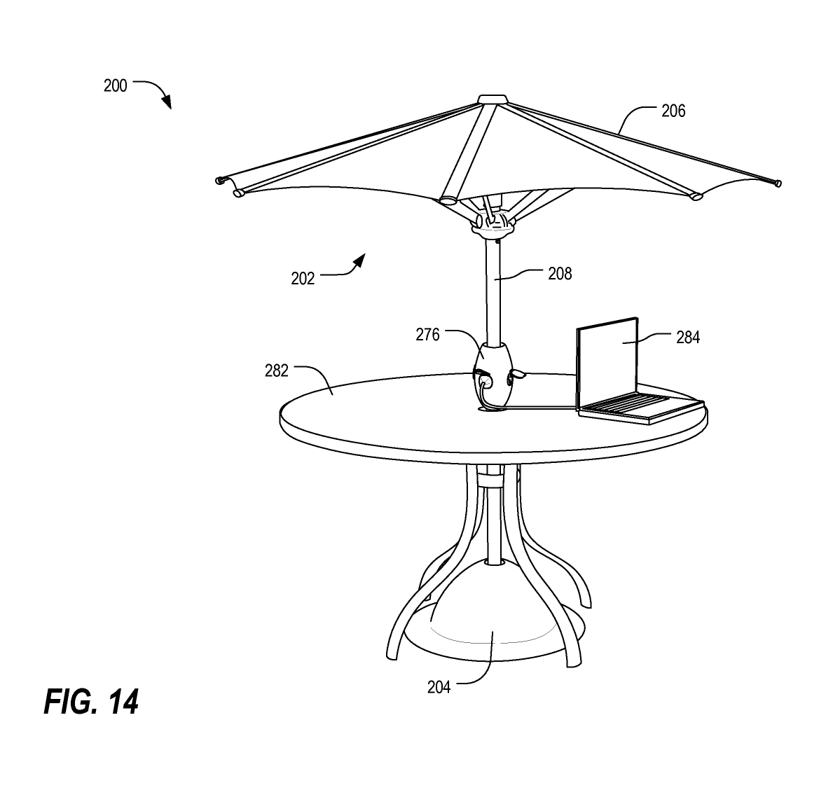

In at least some embodiments, the electrical energy generated by the fabric panels 214 is converted to chemical energy and stored in one or more batteries (not shown) disposed within the base 204. Furthermore, the batteries may be used to power conventional outlets 278, offering household electricity via a conventional three-prong configuration, that are provided in an outlet box 276 mounted to the pole 208. FIG. 13 is an enlarged fragmentary perspective view of a portion of the pole 208 of FIG. 12, showing an integral outlet box 276 mounted to the pole 208. The outlets 278, which may be protected by covers 280, may be used to provide household electricity to standard electrical devices that are plugged into them. In this regard, FIG. 14 is a perspective view of the electricity-generating umbrella-type sunshade 200 of FIG. 12 installed in a conventional center-hole patio table 282. A laptop computer 284 is shown resting on the table 282 and plugged into one of the outlets 278 in the outlet box 276, which is drawing its power supply from the batteries located in the base 204.

In some embodiments, one or more outlets (not shown) may additionally or alternatively be provided in an outlet box (not shown) housed in or attached to the base 204.

Based on the foregoing information, it will be readily understood by those persons skilled in the art that the present invention is susceptible of broad utility and application. Many embodiments and adaptations of the present invention other than those specifically described herein, as well as many variations, modifications, and equivalent arrangements, will be apparent from or reasonably suggested by the present invention and the foregoing descriptions thereof, without departing from the substance or scope of the present invention.

Accordingly, while the present invention has been described herein in detail in relation to one or more preferred embodiments, it is to be understood that this disclosure is only illustrative and exemplary of the present invention and is made merely for the purpose of providing a full and enabling disclosure of the invention. The foregoing disclosure is not intended to be construed to limit the present invention or otherwise exclude any such other embodiments, adaptations, variations, modifications or equivalent arrangements; the present invention being limited only by the claims appended hereto and the equivalents thereof

1. An electricity-generating fabric panel unit, comprising:
a panel of light-collecting fabric produced at least partly from optical waveguides and having an edge; and
an edge assembly disposed along the edge of the fabric panel and adapted to collect light from the optical waveguides of the fabric panel and convert the light to electricity.

2. The electricity-generating fabric panel unit of claim 1, wherein the optical waveguides are flexible optical waveguides.

3. The electricity-generating fabric panel unit of claim 2, wherein the panel of light-collecting fabric is woven from fiber optical waveguides.

4. The electricity-generating fabric panel unit of claim 2, wherein the panel of light-collecting fabric is a nonwoven fabric produced from optical waveguides.

5. The electricity-generating fabric panel unit of claim 3, wherein the panel of light-collecting fabric is woven from fiber optical waveguides that extend in both the longitudinal and lateral directions.

6. The electricity-generating fabric panel unit of claim 3, wherein the panel of light-collecting fabric is woven from fiber optical waveguides that extend in either the longitudinal direction or the lateral direction, but not both.

7. The electricity-generating fabric panel unit of claim 3, wherein the panel of light-collecting fabric is woven from fiber optical waveguides interspersed with wool fibers.

8. The electricity-generating fabric panel unit of claim 3, wherein the panel of light-collecting fabric is woven from fiber optical waveguides interspersed with cotton fibers.

9. The electricity-generating fabric panel unit of claim 3, wherein the panel of light-collecting fabric is woven from fiber optical waveguides interspersed with polyester fibers.

10. The electricity-generating fabric panel unit of claim 3, wherein the panel of light-collecting fabric is woven from fiber optical waveguides interspersed with nylon fibers.

11. The electricity-generating fabric panel unit of claim 2, wherein the panel of light-collecting fabric is produced from a combination of fiber optical waveguides and a conformal composite material.

12. The electricity-generating fabric panel unit of claim 11, wherein the panel of light-collecting fabric is produced from a combination of fiber optical waveguides and fiberglass.

13. The electricity-generating fabric panel unit of claim 11, wherein the panel of light-collecting fabric is produced from a combination of fiber optical waveguides and carbon fiber.

14. The electricity-generating fabric panel unit of claim 11, wherein the panel of light-collecting fabric is produced from a combination of fiber optical waveguides and an aramid synthetic fiber.

15. The electricity-generating fabric panel unit of claim 2, wherein the edge assembly includes a photovoltaic interface.

16. The electricity-generating fabric panel unit of claim 15, wherein the photovoltaic interface includes a strip of photovoltaic cells disposed to receive light directly from exit ports of the optical waveguides.

17. The electricity-generating fabric panel unit of claim 2, wherein the edge of the fabric panel is a first edge and the edge assembly is a first edge assembly, wherein the fabric panel further includes a second edge, and wherein the fabric panel unit further includes a second edge assembly disposed along the second edge of the fabric panel and adapted to collect light from the optical waveguides of the fabric panel and convert the light to electricity.

18. The electricity-generating fabric panel unit of claim 17, wherein the first and second edges of the fabric panel are opposite each other.

19. An electricity-generating fabric panel unit, comprising:
a panel of light-collecting fabric having an edge; and
an edge assembly, adapted to collect light from the fabric panel and convert the light to electricity, that is disposed along the edge of the fabric panel and includes a housing into which the edge of the fabric panel extends.

20. The electricity-generating fabric panel unit of claim 19, wherein the housing includes two case sections attached on opposite surfaces of the fabric panel.

21-136. (canceled)
